(19) United States
(12) Patent Application Publication
(10) Pub. No.: US 2001/0052864 A1
(43) Pub. Date: Dec. 20, 2001

(54) Method of interleaving with redundancy, and A/D converter, D/A converter and track-hold circuit using such method

(76) Inventors: Atsushi Shimizu, Tokyo (JP); Takanori Komuro, Tokyo (JP); Mamoru Tamba, Tokyo (JP); Hideharu Munakata, Tokyo (JP)

Correspondence Address: AGILENT TECHNOLOGIES, Legal Department, 51U-PD, Intellectual Property Administration, P.O. Box 58043, Santa Clara, CA, 95052-8043, US

(21) Appl. No.: 09/841,860

(22) Filed: Apr. 25, 2001

(30) Foreign Application Priority Data
Apr. 27, 2000 (JP) 2000-127104

(51) Int. Cl. H03M 1/00

(52) U.S. Cl. 341/141; 341/144; 341/155

(57) ABSTRACT

In order to prevent spurious signals from being generated in an electronic circuit executing an interleaving operation, a plurality of substantially similar electronic circuits 101, 102, 103 are arranged in parallel and operated in an interleaved manner. When each operating frequency of the electronic circuit is f, in order to obtain a Nf frequency (N is 2 in FIG. 1), more than N pieces (3 in FIG. 1) of electronic circuits are arranged in parallel and used, and electronic circuits 101, 102, 103 are selected for output in an at least pseudo-random manner.

### BACKGROUND OF THE INVENTION

1. Field of the Invention

The present invention relates to an interleaving method with redundancy using a plurality of converters in parallel, and an A/D converter (analog-to-digital converter), a D/A converter (digital-to-analog converter) and a track-hold circuit using the interleaving method. More particularly, the present invention relates to an interleaving method suitable for a conversion between analog and digital data having a high-speed and high-accuracy performance that cannot be easily achieved by a single conversion circuit. The present invention also relates to an A/D converter, a D/A converter and a track-hold circuit capable of operating at high speeds with high accuracy using such interleaving method.

2. Description of the Related Art

Like many other electronic circuits, higher speeds and higher accuracy are in demand for analog circuits used for data conversion such as A/D converters, D/R converters and track-hold circuits. Various techniques have been proposed.

For example, there is one of these techniques in which a plurality of conversion circuits are arranged in parallel and an interleaving operation is executed. This interleaving operation is that a plurality of the same circuits are sequentially changed over and operated to increase an apparent operation clock frequency in an apparatus receiving clock inputs and processing analog quantities. FIG. 11 shows a block diagram of such a conventional example (refer to Japanese Patent Laid-Open No. Heisei 9-252251). In FIG. 11, four A/D conversion circuits 1, 2, 3 and 4 are used. These A/D conversion circuits 1 through 4 are supposed to have the same or similar characteristics. When an operation rate of each A/D conversion circuit is set to f, a clock signal generator 5 generates four-phase clock signals CK1 through CK4 with a cycle T that equals 1/f. These clock signals CK1 through CK4 are input to a multiplexer 6 which is connected to the A/D conversion circuits 1 through 4, receives outputs from these A/D conversion circuits 1 through 4 and outputs a digital output of these A/D conversion circuits 1 through 4.

In other words, as shown in a timing chart of FIG. 12, the A/D conversion circuit 1 executes sample-and-hold operations and analog-digital conversion with the timing provided by the clock signal CK1. The A/D conversion circuit 2 executes sample-and-hold operations and analog-digital conversion with the timing provided by the clock signal CK2. The A/D conversion circuit 3 executes sample-and-hold operations and analog-digital conversion with the timing provided by the clock signal CK3. The A/D conversion circuit 4 executes sample-and-hold operations and analog-digital conversion with the timing provided by the clock signal CK4. Then, by suitably selecting an output among those of the A/D conversion circuits 1 through 4 with the multiplexer 6 at a rear stage, the sampling rate 4f can be realized as an analog-digital converter. Generally, with such a configuration, if the number of A/D conversion circuits that have a sampling rate f and are interleaved is N, a higher sampling rate of Nf is achieved.

In addition, in this conventional A/D converter using such interleaving method, the order of interleaving the A/D conversion circuits is fixed. For example, in the converter shown in FIG. 11, the A/D conversion circuits are interleaved and operated in the order of 1→2→3→4→1→2→. . . as can be seen from FIG. 12.

The analog performance of circuits inevitably varies to some extent from one circuit to another so as to show such variations as offsets, gain differences, amplitude or frequency modulations caused by clock skews, and errors occur as the circuits are continuously switched. For example, if we consider a case in which a sine wave having a frequency fin is inputted to an A/D converter operating with N=4 interleaving, differences among the gains of the A/D conversion circuits are amplitude-modulated at a quarter of the input clock frequency fCLK (f_{CLK=}4f) which is referred to as f_{CLK}/4, due to the interleaving operation, and such modulations appear at the output. Accordingly, large spurious signals occur around the frequency of f_{CLK}/4−f₁ₙ. Such spurious signals are a serious problem for measurement instruments because they are highly frequency dependent. While analog compensation is not impossible for DC offsets, it is difficult to compensate gain differences because gain differences are usually frequency dependent.

To address problems associated with differences in analog performance among such circuits that are continuously switched, such techniques as those described in Japanese Patent Laid-Open No. Heisei 9-252251 and Heisei 11-195988 are known.

According to Japanese Patent Laid-Open No. Heisei 9-252251, in order to realize an A/D converter, a plurality of circuit sets each of which include a sample-and-hold circuit and an analog-digital conversion circuit are arranged in parallel, and the operation of these sets is interleaved. In order to moderate the deterioration of conversion characteristics of the whole circuit, which is caused by differing characteristics of unit circuits in terms of the differing frequency dependency of gains and offset gaps, the order of interleaving is made variable. The order of interleaving is changed to find an optimal performance for the whole conversions circuit, and the interleaving order is then fixed. According to this technique, since the order of interleaving unit circuits is fixed while the A/D converter is operating, the same circuit comes back to do the conversion operation at constant intervals. Accordingly, while it may be OK if an average over the entire frequency range is taken, large spurious signals occur at specific frequencies. Such spurious signals with frequency dependence is not desirable particularly for instruments that require high accuracy and uniform characteristics, such as measurement devices.

According to Japanese Patent Laid-Open No. Heisei 11-195988, a plurality of A/D conversion circuits are arranged in parallel, the interleaving operation is carried out with automatic adjustment of different clock signals for respective A/D conversion circuits operating in parallel. According to this technique, since a plurality of A/D conversion circuits operate periodically, the differing characteristics of the A/D conversion circuits periodically appear at the output. It is therefore impossible to avoid frequency-dependent spurious signals.

### SUMMARY OF THE INVENTION

In view of the above problems in the conventional techniques, it is an object of the present invention to prevent occurrence of frequency-dependent spurious signals and achieve higher accuracy at higher speeds in various circuits, not limited to A/D converters, doing interleaving operations.

According to the present invention, a redundant circuit is added to a plurality of electronic circuits, an interleaving operation is executed among these circuits so as to control frequency-dependent spurious signals. Also, a circuit that is put into a halt state is selected in a pseudo-random manner, so that frequency-dependent spurious signals are controlled.

According to the interleaving method of the present invention, a plurality of substantially similar electronic circuits are arranged in parallel and are operated in an interleaving manner. When the operating frequency of each electronic circuit is f and when the operating frequency of Nf operating frequency is to be (where N is an integer of 2 or more), the number of electronic circuits arranged in parallel and used is chosen to be N+J (where J is a positive integer that is referred to as the “number of redundancy”). Since a redundant circuit is added, one electronic circuit can be selected among the plurality of the electronic circuits and is used for obtaining an output. While it is possible, for example, to use a fixed pattern with some complexity for the selection of such a circuit, it is preferable to select, in a pseudo-random manner, an electronic circuit that is to be used next for output among the J+l electronic circuits that are found by removing the circuits that were used for the present output though the output N−2 times before the present output from the N+J circuits. The interleaving method of the present invention may also be applied to an A/D converter, a D/A converter, a track-hold circuit, and other various electronic circuits and devices that operate in an interleaving manner.

Here, terms of “pseudo-random” and “pseudo-random-number” are used, since it is impossible to realize mathematically perfect random numbers and randomness. Therefore, “random” and “random number” found in this specification mean randomness or random numbers that can be achieved with a conventional method without much difficulty. However, as apparent from the following discussions, in the present specification, the term “random” is used without any intention of limiting the present invention in terms of randomness. Also, as much as the present invention represents an attempt to disperse the energy of frequency- dependent spurious signals in the frequency space, it should be noted that “randomness” is not always required.

Further, the present invention provides an A/D converter comprising three or more A/D conversion circuits that are directly or indirectly connected in parallel with each other and to an input, an output selection circuit that is connected to the outputs of the A/D conversion circuits and that selects one of the connected outputs and uses the selected output as its output, and a clock signal generator for sending a clock signal to the A/D conversion circuits and the output selection circuit, wherein at least one of the plurality of A/D conversion circuits is used for output in accordance with the clock signal from the clock signal generator, so as to operate in an interleaving manner.

In this case, memories may be arranged in series for respective A/D conversion circuits between the A/D conversion circuits and the output selection circuit, so as to use A/D converter circuits of pipeline configuration. Each memory is also driven by the clock signal from the clock signal generator.

Also, if necessary, an input selection circuit may be arranged between the input and the A/D conversion circuits. Then, track-hold circuits operating in an interleaving manner with redundancy may be connected to one or more A/D conversion circuits so as to obtain an A/D converter.

Further, the present invention provides a D/A converter comprising three or more D/A conversion circuits directly or indirectly connected in parallel with each other and to an input, an output selection circuit that is connected to the outputs of the A/D conversion circuits and that selects one of the connected outputs and uses the selected output as its output, and a clock signal generator for sending a clock signal to the D/A conversion circuits and the output selection circuit, wherein at least one of said plurality of D/A conversion circuits is put in a pause or waiting mode, so as to operate in an interleaving manner.

If necessary, memories may be arranged in series for respective D/A conversion circuits between the D/A conversion circuits and the output selection circuit, and an input selection circuit is arranged between the input and the D/A conversion circuits.

### BRIEF DESCRIPTION OF THE DRAWINGS

The above and other objects, advantages, and features of the present invention will be more apparent from the following description taken in conjunction with the accompanying drawings in which:

FIG. 1 is a block diagram showing a first embodiment according to the present invention;

FIG. 2 is a timing chart showing the first embodiment according to the present invention;

FIG. 3 is a block diagram showing one example of a clock signal generator of the first embodiment according to the present invention;

FIG. 4 is a block diagram showing a second embodiment according to the present invention;

FIG. 5 is a timing chart showing a second embodiment according to the present invention;

FIG. 6 is a block diagram showing an A/D converter including a track-hold circuit executing an interleaving operation of a third embodiment according to the present invention;

FIG. 7 is a block diagram showing a D/A converter of a fourth embodiment according to the present invention;

FIG. 8 is a block diagram showing a D/A converter of a fifth embodiment according to the present invention;

FIG. 9 is a graph showing a signal spectrum in an A/D conversion circuit of the conventional example;

FIG. 10 is a graph showing a signal spectrum in an A/D conversion circuit of the present invention;

FIG. 11 is a block diagram showing a conventional example of an A/D conversion circuit; and

FIG. 12 is a timing chart of the conventional example.

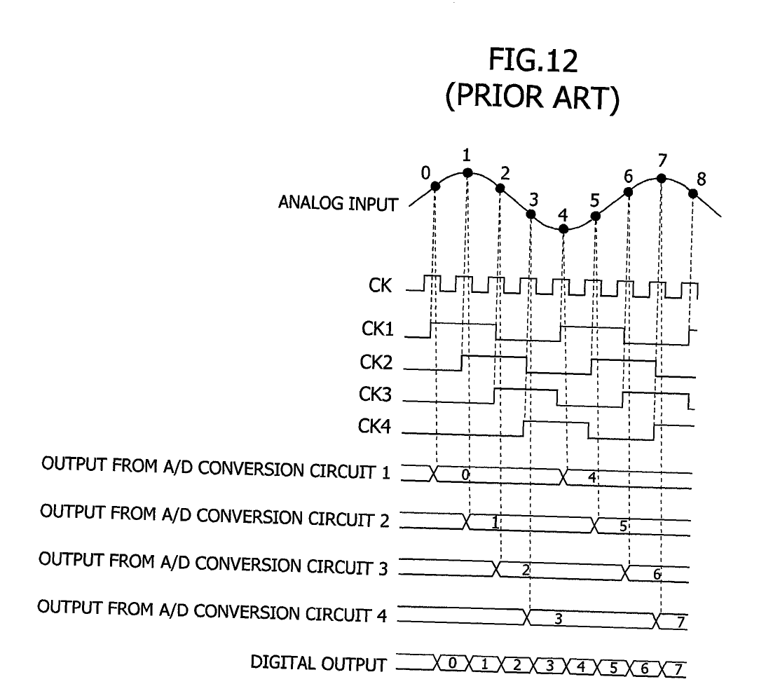

### DETAILED DESCRIPTION OF THE PREFERRED EMBODIMENTS

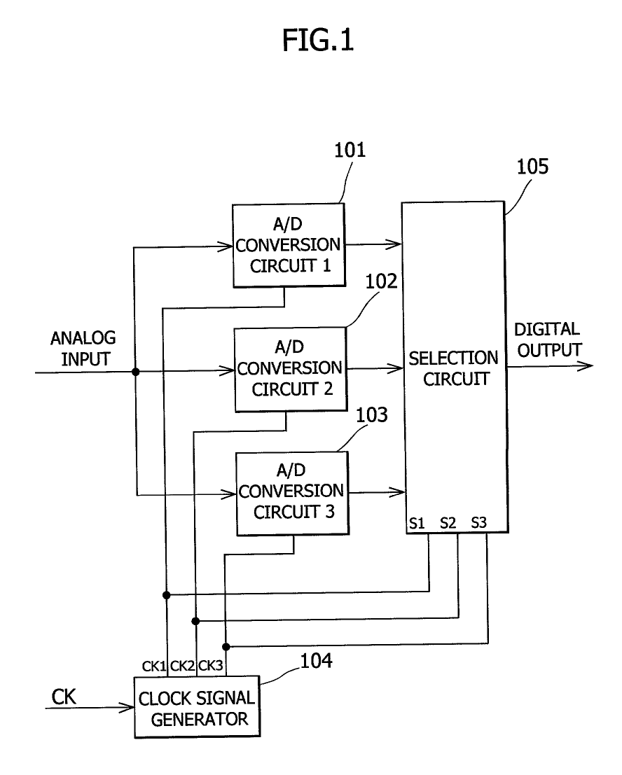

FIG. 1 shows a first embodiment for an A/D converter of the present invention using three A/D conversion circuits. This A/D converter is equivalent to a conventional A/D converter having two A/D conversion circuits which are operated in an interleaving manner and to which another A/D conversion circuit is added so as to provide redundancy.

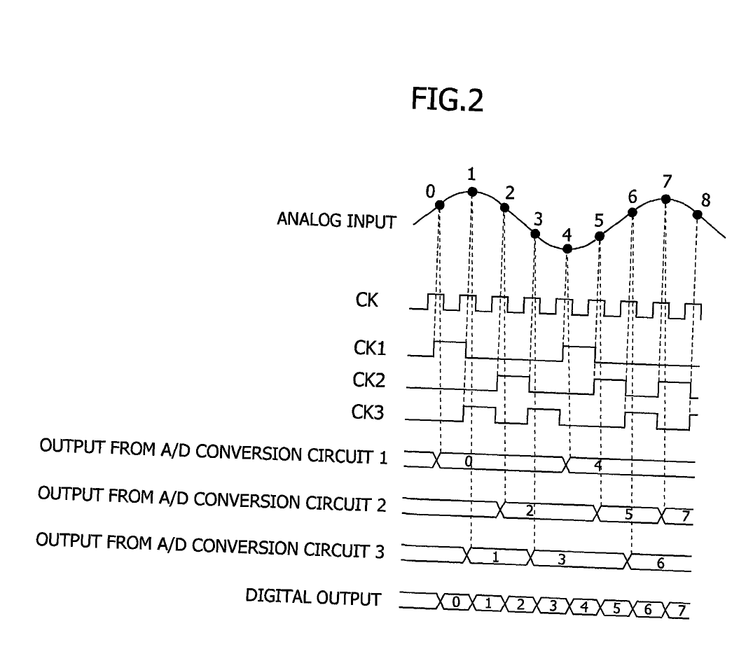

As shown in FIG. 1, in the first embodiment, outputs from A/D conversion circuit 1 (101), A/D conversion circuit 2 (102) and A/D conversion circuit 3 (103) that are connected in parallel with each other and to one analog input are inputted into a selection circuit (105). These A/D conversion circuits 101, 102, 103 and the selection circuit 105 receive clock signals from a clock signal generator 104. The clock signal generator 104 is provided with a pseudo-random number generating circuit (not shown) and outputs random clock outputs CK1, CK2, CK3 show in FIG. 2 to each of the A/D conversion circuit 101, 102, 103 and to the selection circuit 105.

Based on pseudo-random numbers generated in the pseudo- random number generating circuit, any one of outputs from the three A/D conversion circuits 101, 102, 103 is selected in the selection circuit 105 as the digital output of the A/D converter. Two of the three A/D conversion circuits are always in operation (operating in a normal data acquisition mode at the operating frequency) and one A/D conversion circuit is waiting (in an idling state). When an output of one A/D conversion circuit is used as the output of the whole A/D converter, an A/D converter of which output is next used as an output (an A/D conversion circuit obtaining new data) can be selected between the two remaining A/D conversion circuits. In this case, it is necessary to avoid successively using the same A/D conversion circuit more than once. For example, when A/D conversion circuit 1 is used at one moment, it is necessary to use A/D conversion circuit 2 or A/D conversion circuit 3 in the next clock cycle, but not the same A/D conversion circuit 1. When A/D conversion circuit 2 is currently selected, A/D conversion circuit 1 or A/D conversion circuit 3 is selected for the next moment. The operation goes on in this way.

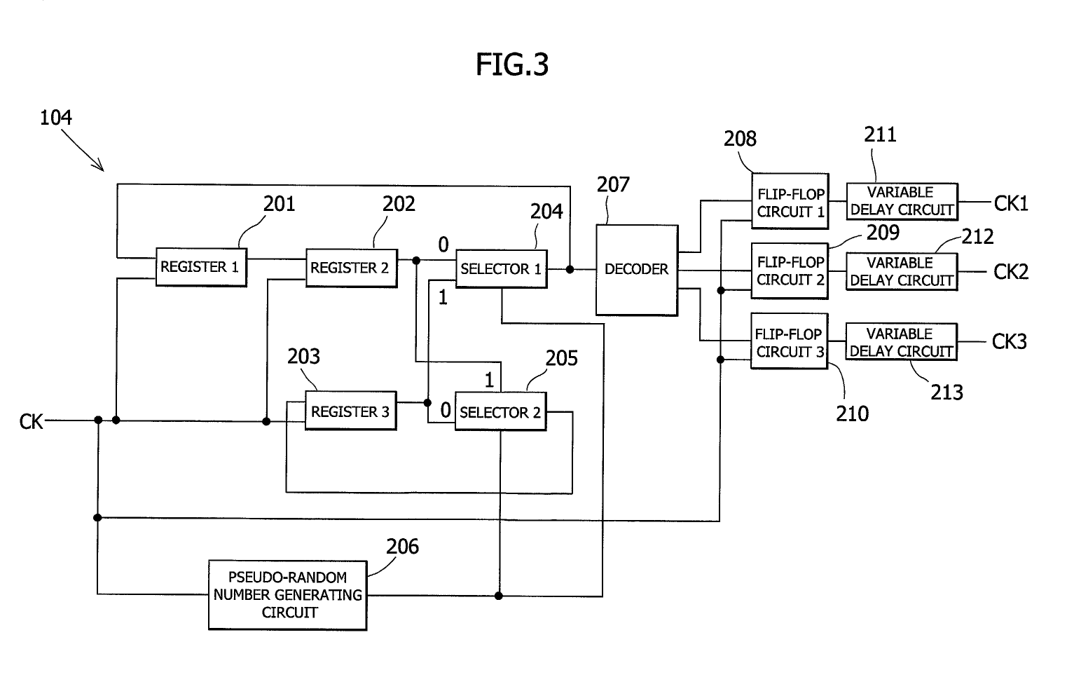

FIG. 3 shows one example of the clock signal generator 104 which may be used in the first embodiment. A clock signal CK is inputted into the clock signal generator 104 from the outside. As described above, since it is necessary to avoid that the same A/D conversion circuit is successively selected twice, it is necessary to memorize which A/D conversion circuit was selected for the last time. Registers 1, 2, 3 (201, 202, 203) are combined with selectors 1, 2 (204, 205). A pseudo-random number generating circuit 206 outputs either 0 or 1 at random (even though it is not perfectly random).

Register 1 memorizes the currently used A/D conversion circuit, register 2 memorizes the A/D conversion circuit used last time, and register 3 memorizes the A/D conversion circuit unused at that moment and for the last moment. Within the constraint that the same A/D conversion circuit cannot be successively used twice, the next A/D conversion circuit is selected from register 2 or register 3 in response to the output from the pseudo-random number generating circuit 206.

When the output from the pseudo-random number generating circuit 206 is 0, the A/D conversion circuit memorized in register 2 is used for the next moment. The information held in register 2 is transferred to register 1 through selector 1, the information held in register 1 is transferred to register 2, and information held in register 3 is transferred to register 3 through selector 2. As a result, information held in register 3 is maintained in register 3 as it is. When the output from the pseudo-random number generating circuit 206 is 1, the A/D conversion circuit memorized in register 3 is used in the next time. The information held in register 3 is transferred to register 1 through selectors 1, the information held in register 1 is transferred to register 2, and the information held in register 2 is transferred to register 3 through selector 2. In any case, since the A/D conversion circuit currently used is memorized in register 1, that particular A/D conversion circuit is excluded from the selection for the next. Thus, the same A/D conversion circuit is never selected successively.

In this embodiment, the double sampling rate is achieved with three A/D conversion circuits. Similar configurations are available for different cases. For example, when the quadruple sampling rate is realized with five A/D conversion circuits, by providing a circuit that would correspond to a three-step shift register instead of register 1 shown in FIG. 3, it is possible to obtain a double or higher sampling rate.

The output from selector 1 is inputted into a decoder 207 so as to be passed on to three flip-flop circuits 208, 209, 210 driven by variable delay circuits 211, 212, 213 respectively connected to flip-flop circuits 208, 209, 210 in series, and is outputted as three clock signals CK1, CK2, CK3.

Selection circuit 105 merely selects one from the outputs of the A/D conversion circuit 101, 102, 103 in response to the clock signals CK1, CK2, CK3 as the output of the whole A/D converter.

For example, in this embodiment, when it is assumed that the maximum frequency of each A/D conversion circuit 101, 102, 103 is 100 MHz, the maximum sampling frequency obtained as an interleaving A/D converter is 200 MHz. The clock signal generator 104 receives a clock of 200 MHz and generates a clock signal of which the maximum frequency having the random characteristic shown in the timing chart of FIG. 2 is 100 MHz, each A/D conversion circuit 101, 102, 103 is driven by this clock signal of which the maximum frequency is 100 MHz, and selection circuit 105 is driven by the maximum frequency of 200 MHz.

It is possible to raise the maximum sampling frequency up to 400 MHz when the number of A/D conversion circuits arranged in parallel is increased to five using a similar A/D conversion circuit arrangement. In such the case, it is necessary to memorize A/D conversion circuits already selected in the last two clock cycles, and it is necessary to select the next A/D conversion circuit at random from the two A/D conversion circuits excluding the currently used A/D conversion circuit and the two A/D conversion circuits selected used during the last two clock cycles.

In this way, an A/D conversion circuit is selected at random and used, and thereby it is possible to prevent each A/D conversion circuit from periodically operating and restrain strong spurious signals occurring at specific frequencies. According to the present invention, although the power of the spurious signals is not reduced, this power is spread over a large frequency range, so as to eliminate the strong frequency dependency. Accordingly, while errors at frequencies other than the specific frequencies at which spurious signals appear would increase slightly, this increase is extremely small. Overall, it is much more advantageous to have the large spurious signals occurring at the specific frequencies removed.

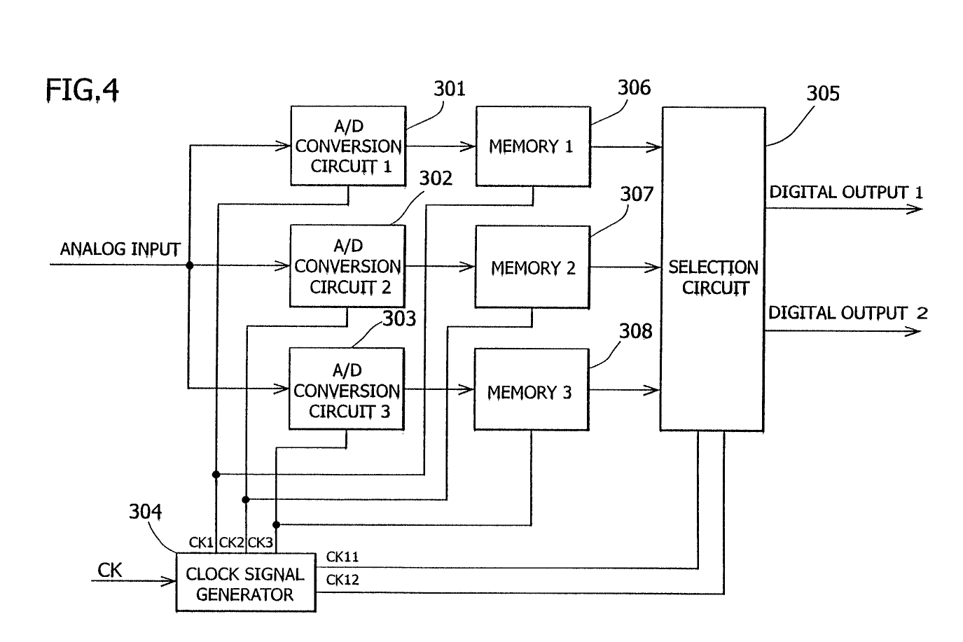

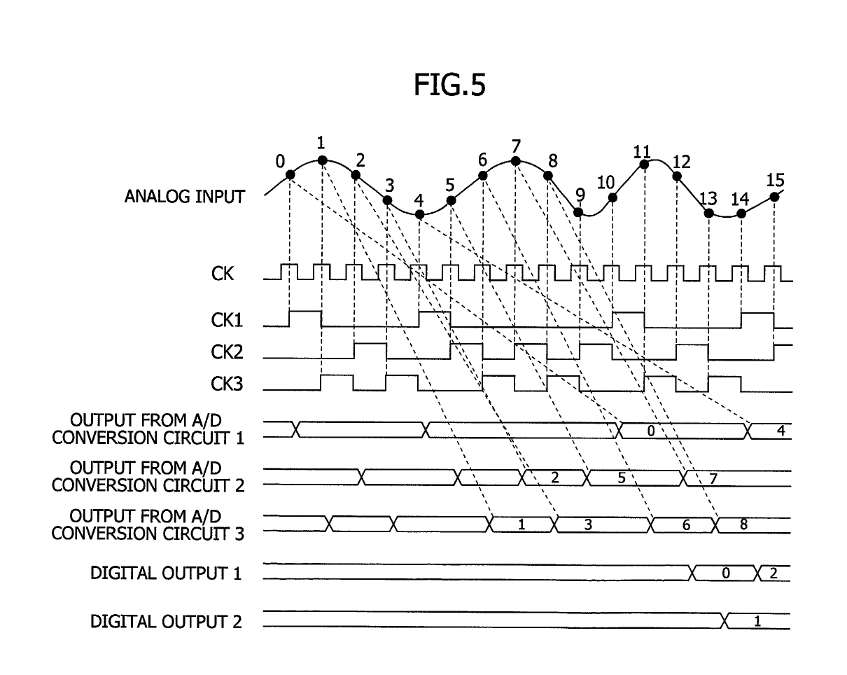

FIG. 4 shows the second embodiment of the present invention. High-speed A/D converters often involve a pipeline configuration. In such cases, as shown in FIG. 4, memories 306, 307, 308 respectively connected to the outputs of A/D conversion circuit 1, 2, 3 (301, 302, 303) in series are provided. FIG. 5 shows an example of the timing chart for this second embodiment. The clock input is basically similar to that of the first embodiment; however, the output from the A/D converter is delayed since the A/D converters have a pipeline configuration. In the conventional interleaving method, clock signals are inputted in a fix order, and data are outputted in the order measurements are done. According to the present invention, pseudo-random clock signals are used, the time period required for a particular piece of data to be outputted from the A/D converter varies from one piece of data to another. Memories 306, 307, 308 are now necessary for the outputs from the A/D converters in order to absorb such timing differences. Here, two-port memories (FIFO memories or First-In-First-Out memories) are used, and data from A/D conversion circuits 301, 302, 303 are written into the memories and stored data are read out at the same time. The A/D conversion circuits, memories and selection circuit are driven by clock signals from clock signal generator 304.

Here, since two interleaved outputs are read, the selection circuit for reading data suffices to have a speed equal to that of the A/D conversion circuit. Generally, by interleaving or banking the outputs from the A/D converter, the number of outputs from the A/D converter may be set to M (M is integer of 2 or more). Then, the selection circuit is driven at a frequency of 1/M times the sampling frequency. Thus, simpler circuits can be used advantageously.

In addition, two-port memories are generally expensive and have only small capacities. One-port memories may be used, and software programs may be used to rearrange data after measurements and when data is read out of the converter. Further, a clock signal generating circuit, a plurality of A/D conversion circuits and a selection circuit may be designed into one integrated circuit and clock signals of respective stages may be changed, so that memories for rearranging output data can be omitted even if the A/D converter circuits have a pipeline structure.

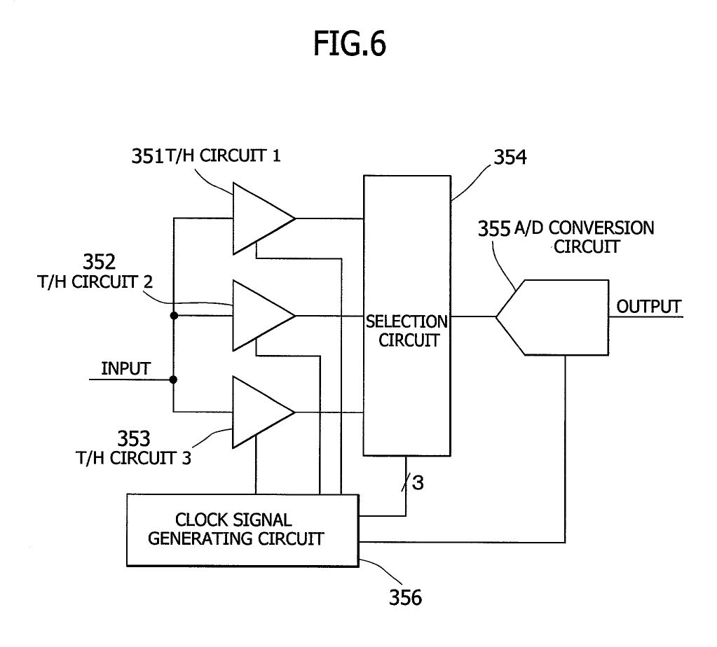

FIG. 6 shows the third embodiment in which the present invention is applied to an A/D converter including redundant track-hold circuits. An analog input is connected to three track-hold circuits 351, 352, 353 (T/H circuit 1, 2, 3) connected in parallel with each other. The outputs from track-hold circuits 351, 352, 353 are connected to selection circuit 354 for selecting one output among the three outputs. An output from selection circuit 354 is connected to A/D conversion circuit 355, and a digital output is obtained. It is similar to the above-mentioned embodiments in that one clock signal generating circuit 356 is provided in order to drive all of these circuits.

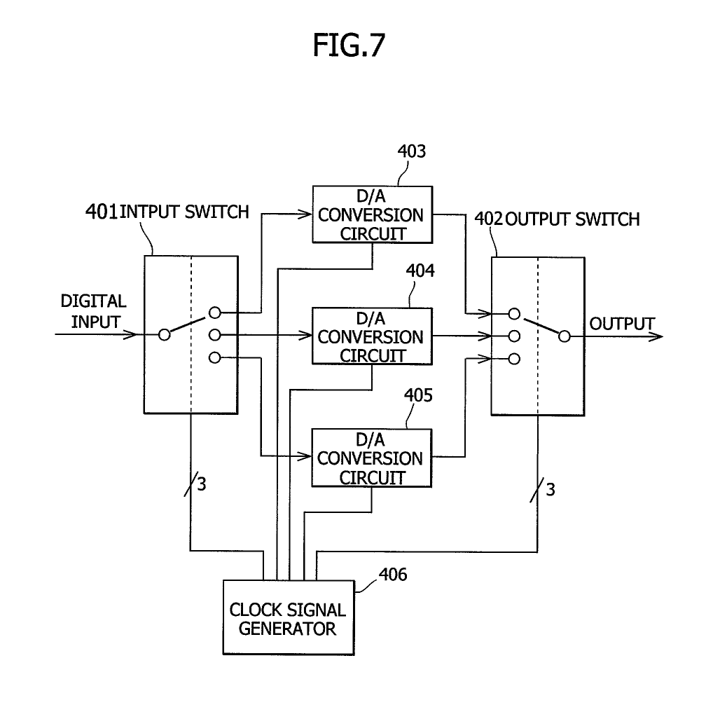

FIG. 7 shows the fourth embodiment wherein the present invention is applied to a D/A converter. As shown in FIG. 7, an input switch 401 for digital signals is provided on the input side, and an output switch 402 for analog signals is provided on the output side of the converter. The input switch 401 and output switch 402 are driven by a clock signal generated by clock signal generator 406 together with the D/A conversion circuits 403, 404, 405. The interleaving operation and redundancy are much similar to those discussed for the embodiments explained with reference to FIG. 1 or the like. Therefore, the same discussions are not repeated here.

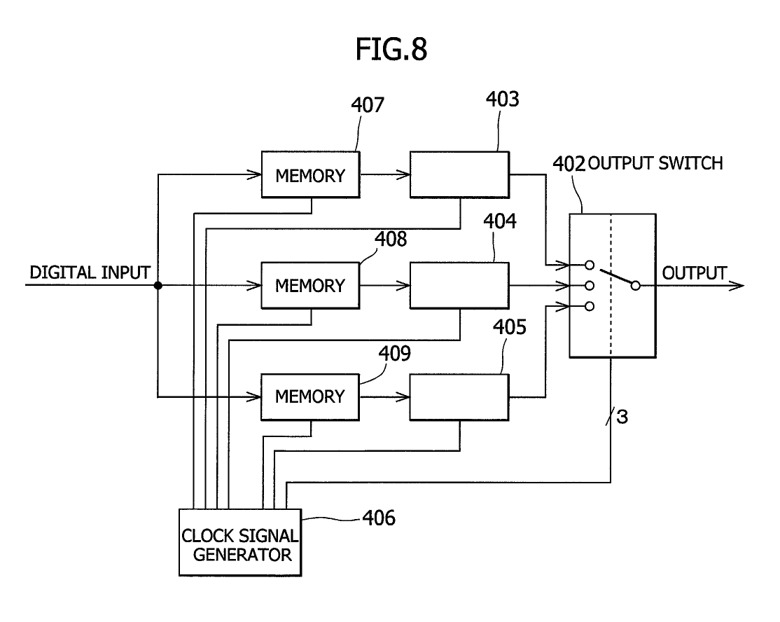

In addition, if D/A conversion circuits that do not accept an input unless a clock signal is not inputted are used, it is possible to omit the input switch 401. Accordingly, the input may be directly connected to the D/A conversion circuits when operated. Further, the present invention can be applied to a configuration of the fifth embodiment shown in FIG. 8. In FIG. 8, memories 407, 408, 409 are provided in series between D/A conversion circuits 403, 404, 405 and the input instead of the input switch 401 shown in FIG. 7. When the D/A conversion circuits are interleaved, the order of switching the D/A conversion circuits is pseudo-random. However, it is possible to know this pseudo-random order beforehand. According to such known order, data are written into the memories respectively connected to the D/A conversion circuits, and the input switch can be omitted.

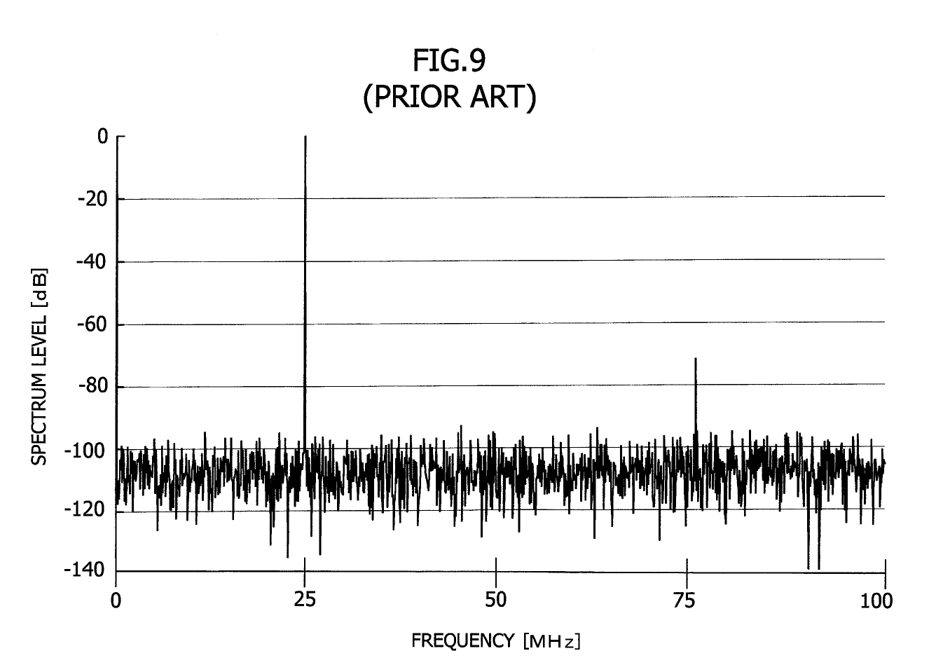

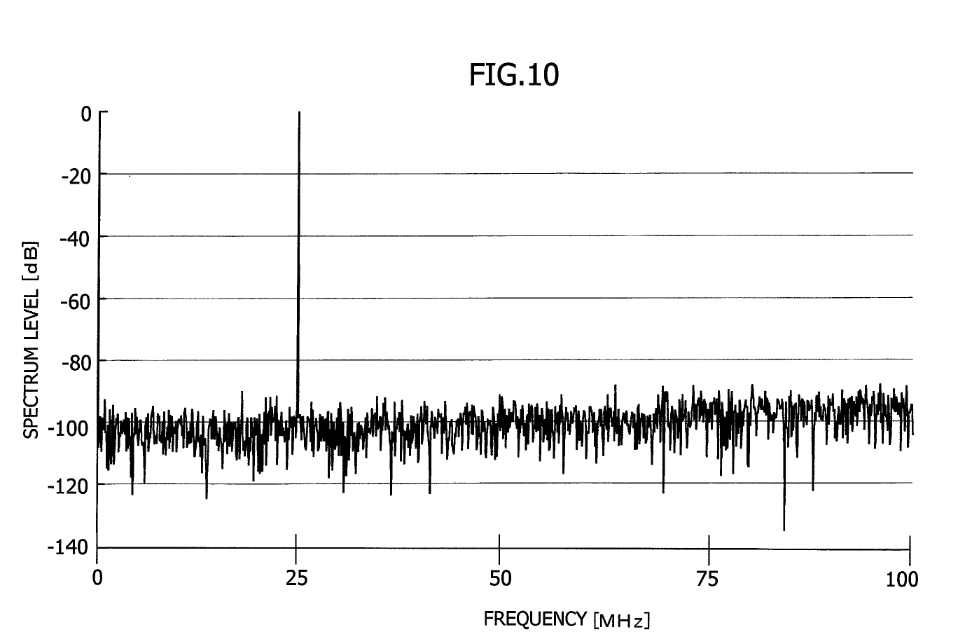

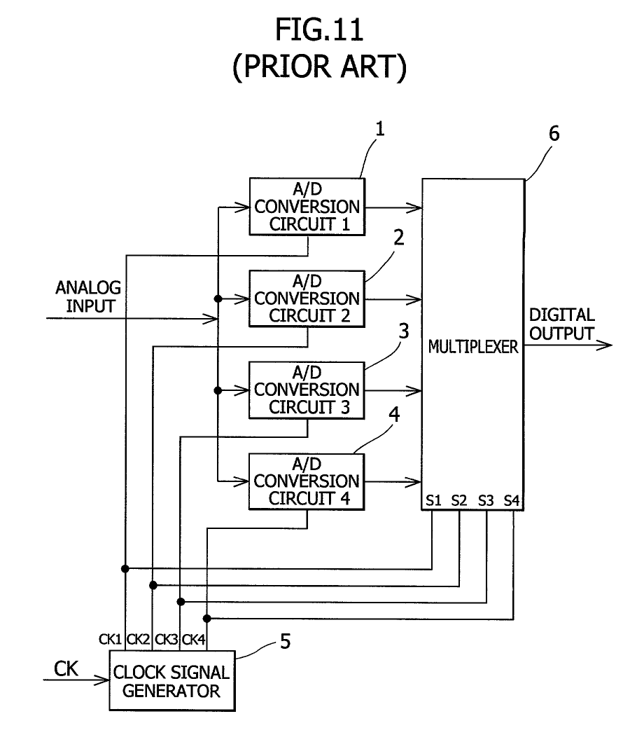

FIGS. 9 and 10 respectively show simulation results for the conventional circuit configuration shown in FIG. 11 and for the A/D converter shown in

FIG. 1, when some quantumization noise with 12 bits is added. In the circuit configuration shown in FIG. 1, one A/D conversion circuit is redundant. Only two A/D conversion circuits among the three operate at a given time and one A/D conversion circuit is waiting.

It is assumed that the signal frequency is 25 MHz, and the sampling frequency for one A/D conversion circuit is 100 MHz. Accordingly, an equivalent sampling frequency for the A/D converter is 100 MHz×2=200 MHz. The number of sampling points is set to 1024. As to mismatching of gains among the A/D conversion circuits, a peak-to-peak ratio is 0.05%. As apparent from FIG. 9 (the conventional example) and FIG. 10 (the present invention), the worst spurious signal in the conventional example appears at 75 MHz and a spurious free dynamic range (SFDR) is −71.7 dB. On the other hand, in FIG. 10, we see little spurious signals, and SFDR is −88.1 dB. The S/N ratio for FIG. 9 is 69.8 dB, and that for FIG. 10 is 67.8 dB.

As above described, according to the present invention, when a plurality of circuits connected in parallel are interleaved, redundant circuits are provided and circuits are selected and operated with some ordering (preferably, in the order determined by pseudo-random numbers) among these circuits. It is possible to spread spurious energy concentrated at specific frequencies over a large frequency range, and it is possible to significantly improve the spurious free dynamic range (SFDR).

The entire disclosure of Japanese Patent Application No. 2000-127104 filed on Apr. 27, 2000 including the specification, claims, drawings and abstract are incorporated herein by reference in its entirety.

What is claimed is:

1. A method of interleaving operation with redundancy for a plurality of substantially similar electronic circuits arranged in parallel to each other, comprising the steps of providing more than N pieces of said electronic circuits (where N is an integer of 2 or more), so as to substantially realize an apparent operating frequency of Nf where an operating frequency of each electronic circuit is f, and switching said electronic circuits.

2. The interleaving method according to claim 1, wherein the electronic circuit of which output is used next is selected in an at least pseudo-random manner among remaining electronic circuits, of which number is the total number of electronic circuits arranged in parallel minus N−1, found by excluding the electronic circuit currently used and the electronic circuits used for N−2 clock cycles prior to the current cycle from the totality of said electronic circuits.

3. The interleaving method according to claim 1, wherein outputs of two and more among said electronic circuits are interleaved and used as an output.

4. An A/D converter executing the interleaving method according to claim 1.

5. A D/A converter executing the interleaving method according to claim 1.

6. A track-hold circuit executing the interleaving method according to any one of claims 1.

7. An A/D converter comprising:
three or more A/D conversion circuits arranged in parallel with each other and directly or indirectly connected to an input;
an output selection circuit connected to outputs of said A/D conversion circuits and selecting one of connected outputs and outputting a selected output; and
a clock signal generator for sending a clock signal to said A/D conversion circuits and said output selection circuit,
wherein at least one of said plurality of A/D conversion circuits is held in a waiting mode in accordance with clock signals from said clock signal generator, and an interleaving operation is executed among said A/D conversion circuits.

8. The A/D converter according to claim 7, wherein while said A/D conversion circuits operate at frequency f, an operating frequency of Nf is obtained for said A/D converter by said interleaving operation (where N is an integer of 2 or more), an A/D conversion circuit of which output is used next is selected in an at least pseudo-random manner among remaining A/D conversion circuits, of which number is the total number of more than N A/D conversion circuits arranged in parallel with each other minus N'11, found by excluding the A/D conversion circuit currently used and the A/D conversion circuits used for N−2 clock cycles prior to the current cycle from the totality of said more than N A/D conversion circuits.

9. The A/D converter according to claim 7, wherein memories are respectively arranged in series for said A/D conversion circuits between said A/D conversion circuits and said output selection circuit.

10. The A/D converter according to claim 7, wherein an input selection circuit is arranged between said input and said A/D conversion circuits.

11. An A/D converter comprising:
a plurality of track-hold circuits that are connected in parallel with each other and that execute the interleaving method according to claim 1;
a selection circuit connected to outputs of said track-hold circuits; and
at least one A/D conversion circuit connected to an output of said selection circuit.

12. A D/A converter comprising:
three or more D/A conversion circuits that are arranged in parallel with each other and that are directly or indirectly connected to an input;
an output selection circuit connected to said D/A conversion circuits for selecting one of connected outputs and outputting a selected output; and
a clock signal generator for sending a clock signal to said D/A conversion circuits and said output selection circuit,
wherein at least one of said plurality of D/A conversion circuits is held in a waiting mode in accordance with clock signals from said clock signal generator, and an interleaving operation is executed among said D/A conversion circuits.

13. The D/A converter according to claim 12, wherein while said D/A conversion circuits operate at frequency f, an apparent operating frequency of Nf is obtained for said D/A converter by said interleaving operation (where N is an integer of 2 or more), a D/A conversion circuit of which output is used next is selected in an at least pseudo-random manner among remaining D/A conversion circuits, of which number is the total number of more than N D/A conversion circuits arranged in parallel with each other minus N−1, found by excluding the D/A conversion circuit currently used and the D/A conversion circuits used for N−2 clock cycles prior to the current cycle from the totality of said more than N D/A conversion circuits.

14. The D/A converter according to claim 12, wherein memories are respectively arranged in series for said D/A conversion circuits between said D/A conversion circuits and said output selection circuit.

15. The D/A converter according to claim 12, wherein an input selection circuit is arranged between said input and said D/A conversion circuits.
